(19) United States
(12) Patent Application Publication
(10) Pub. No.: US 2014/0034952 A1
(43) Pub. Date: Feb. 6, 2014

(54) Liquid Crystal Display Device, Array Substrate and Manufacturing Method Thereof

(71) Applicant: Cheng-hung Chen, Shenzhen (CN)

(72) Inventor: Cheng-hung Chen, Shenzhen (CN)

(73) Assignee: SHENZHEN CHINA STAR OPTOELECTRONICS TECHNOLOGY CO. LTD., Shenzhen (CN)

(21) Appl. No.: 13/582,746

(22) PCT Filed: Aug. 3, 2012
(86) PCT No.: PCT/CN12/79670

§ 371 Date: Sep. 5, 2012

(30) Foreign Application Priority Data
Jul. 31, 2012 (CN) 201210269093.9

(51) Int. Cl. H01L 29/786; H01L 33/08

(52) U.S. Cl. 257/59; 438/34; 257/72; 257/E33.066; 257/E29.273

(57) ABSTRACT

The present invention provides a manufacturing method for array substrate, including: forming a first conductive layer, a first isolator layer, a second conductive layer and a second isolator layer on a substrate from bottom up, the first conductive layer for forming electrically connected scan line and control terminal of switch transistor, performing dry etch on the second isolator layer to form via hole, and forming a third conductive layer on the second isolator layer for forming data line. The present invention also provides an arrays substrate and a liquid crystal display device. As such, the present invention can reduce the possibility of electrostatic explosion during array substrate manufacturing process and improve the yield rate of array substrate.

### BACKGROUND OF THE INVENTION

1. Field of the Invention

The present invention relates to the field of liquid crystal displaying techniques, and in particular to a liquid crystal display device, array substrate and manufacturing method thereof.

2. The Related Arts

The manufacturing process of liquid crystal display panel usually comprises array process, cell process and module process. The array process is to manufacture a thin film transistor glass substrate, also called array substrate, as the first process of manufacturing liquid crystal display panel. The quality of thin film transistor glass substrate has a great impact on the subsequent manufacturing processes, or even a defining factor on the quality of liquid crystal display panel.

The array process usually comprises five steps of mask process (5PEP) to form thin film transistor structure on glass free of impurity. As shown in FIGS. 1-3, in the first process SP1, a first metal layer 11 is plated on glass 1 for serving as gate terminals and scan lines of thin film transistors; then, in the second process SP2, isolator layer 12 is formed on first metal layer 11 and a semiconductor layer 13 is formed on top of first metal layer 11 forming gate terminals of thin film transistors and corresponding isolator layer 12; in the third process SP3, a second metal layer 14 is plated on top of isolator layer 12 and semiconductor layer 13 for forming data lines, source terminals and drain terminals of thin film transistors; in the fourth process SP4, a passivation layer (PV) 15 is formed on second metal layer 14 and non-covered semiconductor layer 13 and isolator layer 12 by second metal layer 14 and via holes 151 are formed on passivation layer 15 at locations corresponding to drain terminals of thin film transistors formed by second metal layer 14; and in the fifth process SP5, a transparent conductive layer 16 is formed on passivation layer 15 for serving as pixel electrodes, and transparent conductive layer 16 is electrically connected through via holes 151 to drain terminals of thin film transistors formed by second metal layer 14 to realize electrical connection of pixel electrodes through via holes 151 to drain terminals of thin film transistors.

In the above 5PEP, first metal layer 11 is for scan line and forming gate terminal of thin film transistor, second metal layer 14 is for forming data line, source terminal and drain terminal of thin film transistor. In liquid crystal display panel, the scan lines and the data lines will cross each other. Therefore, first metal layer 11 and second metal layer 14 will overlap. When designing peripheral circuitry of liquid crystal display panel, to reduce the impedance of signal path and test path, the overlapping structure of first metal layer 11 and second metal layer 14 is widely used so to transmit same signals to reduce first metal layer 11 and second metal layer 14 as well as the signal delay.

However, in the fourth process SP4 of 5PEP, the formation of via holes 151 on passivation layer 15 is often through dry etch, i.e., plasma reaction is used to etch passivation layer 15 to form via holes 151. At this point, first metal layer 11 and second metal layer 14 are not electrically connected; therefore a voltage difference exists between first metal layer 11 and second metal layer 14 because of plasma. When the voltage difference is large, a breakdown of isolator layer 12 between first metal layer 11 and second metal layer 14 is possible to cause electrostatic explosion or short circuit between the two metal layers.

### SUMMARY OF THE INVENTION

The technical issue to be addressed by the present invention is to provide a liquid crystal display device, array substrate and manufacturing method thereof, to reduce the possibility of electrostatic explosion during array substrate manufacturing process and improve the yield rate of array substrate.

The present invention provides a manufacturing method for array substrate, which comprises: forming a first conductive layer, a first isolator layer, a second conductive layer and a second isolator layer on a substrate from bottom up, the first conductive layer for forming electrically connected scan line and control terminal of switch transistor, number of the second conductive layers being at least one, for forming input terminal and output terminal of switch transistor and transparent pixel electrode, output terminal electrically connected to pixel electrode; performing dry etch on the second isolator layer to form via hole; forming a third conductive layer on the second isolator layer and making third conductive layer electrically connected through via hole to input terminal of switch transistor, the third conductive layer for forming data line; wherein the step of forming a first conductive layer, a first isolator layer, a second conductive layer and a second isolator layer on a substrate from bottom up comprising: forming the first metal layer on the substrate, performing etching on the first metal layer to form electrically connected scan line and gate terminal of thin film transistor serving as switch transistor; forming the first isolator layer on gate terminal of the thin film transistor and scan line; forming transparent conductive layer on the first isolator layer; performing etching on transparent conductive layer to form source terminal and drain terminal of thin film transistor and pixel electrode, and electrically connecting drain terminal of thin film transistor and pixel electrode; forming the second isolator layer on top of source terminal and drain terminal of thin film transistor and pixel electrode; and the step of performing dry etch on the second isolator layer to form via hole comprising: performing dry etch on the second isolator layer corresponding to source terminal of thin film transistor to form via hole between the second isolator layer and source terminal of thin film transistor.

According to a preferred embodiment of the present invention, a step after forming the first isolator layer on gate terminal of the thin film transistor and scan line comprises: forming a semiconductor layer on the first isolator layer corresponding to gate terminal of thin film transistor and making source terminal and drain terminal of thin film transistor connected respectively to the semiconductor layer.

According to a preferred embodiment of the present invention, the step of performing dry etch on the second isolator layer corresponding to source terminal of thin film transistor comprises: using dry etch based on plasma etching to perform dry etch on the second isolator layer corresponding to source terminal of thin film transistor.

According to a preferred embodiment of the present invention, the step of forming a third conductive layer on the second isolator layer and making third conductive layer electrically connected through via hole to input terminal of switch transistor comprises: forming the second metal layer on the second isolator layer; performing etching on the second metal layer to form data line and making data line electrically connected through via hole to source terminal of thin film transistor.

The present invention provides an array substrate, which comprises a substrate; scan line and control terminal of switch transistor, disposed on the substrate and electrically connected to each other; a first isolator layer, disposed on top of scan line and control terminal of switch transistor; input terminal and output terminal of switch transistor and transparent pixel electrode, disposed on top of the first isolator layer, output terminal electrically connected to pixel electrode, semiconductor being disposed between output terminal and input terminal; a second isolator layer, disposed on top of input terminal and output terminal of switch transistor and pixel electrode, via hole being disposed on the second isolator layer at locations corresponding to input terminal of switch transistor; and data line, disposed on via hole area of the second isolator layer, data line electrically connected through via hole to input terminal of switch transistor.

According to a preferred embodiment of the present invention, the switch transistor is thin film transistor, the control terminal is gate terminal of the thin film transistor, the input terminal and the output terminal are source terminal and drain terminal of the thin film transistor respectively.

According to a preferred embodiment of the present invention, the source terminal and the drain terminal of the thin film transistor and the pixel electrode belong to a transparent conductive layer.

The present invention provides a liquid crystal display device, which comprises an array substrate, the array substrate comprises: a substrate; scan line and control terminal of switch transistor, disposed on the substrate and electrically connected to each other; a first isolator layer, disposed on top of scan line and control terminal of switch transistor; input terminal and output terminal of switch transistor and transparent pixel electrode, disposed on top of the first isolator layer, input terminal electrically connected to pixel electrode, semiconductor being disposed between output terminal and input terminal; a second isolator layer, disposed on top of input terminal and output terminal of switch transistor and pixel electrode, via hole being disposed on the second isolator layer at locations corresponding to input terminal of switch transistor; and data line, disposed on via hole area of the second isolator layer, data line electrically connected through via hole to input terminal of switch transistor.

According to a preferred embodiment of the present invention, the switch transistor is thin film transistor, the control terminal is gate terminal of the thin film transistor, the input terminal and the output terminal are source terminal and drain terminal of the thin film transistor respectively.

According to a preferred embodiment of the present invention, the source terminal and the drain terminal of the thin film transistor and the pixel electrode belong to a transparent conductive layer.

The efficacy of the present invention is that to be distinguished from the state of the art. The present invention forms the first conductive layer for scan line and control terminal of switch transistor, then forms first isolator layer, second conductive layer and second isolator layer subsequently, performs dry etch to form via holes on the second isolator layer, and finally forms the third conductive layer on top of the second isolator layer for data line. Because when performing dry etch on the second conductive layer to form via holes, the third conductive layer for data line is yet formed, no scan line and data line overlapping area exists when performing dry etch. Therefore, the present invention can reduce the possibility of electrostatic explosion during array substrate manufacturing process and improve the yield rate of array substrate.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort. In the drawings:

FIG. 1 is a schematic view showing the structure of a known array substrate;

FIG. 2 is across-sectional view of the array substrate in FIG. 1 along the AB direction;

FIG. 3 is a schematic view of 5PEP of the array substrate of FIG. 1;

FIG. 4 is a flowchart of a manufacturing method for array substrate according to the present invention;

FIG. 5 is a schematic view of 5PEP of the array substrate of FIG. 4;

FIG. 6 is a flowchart showing an embodiment of forming a first conductive layer, first isolator layer, second conductive layer and second isolator layer on the substrate from bottom up when first conductive layer being first metal layer and second conductive layer being transparent conductive layer in FIG. 4;

FIG. 7 is a flowchart showing an embodiment of forming third conductive layer on top of second isolator layer when third conductive layer being second metal layer in FIG. 4;

FIG. 8 is a schematic view showing the structure of an embodiment of an array substrate of the present invention; and

FIG. 12 is a cross-sectional view of array substrate along CD direction in FIG. 8.

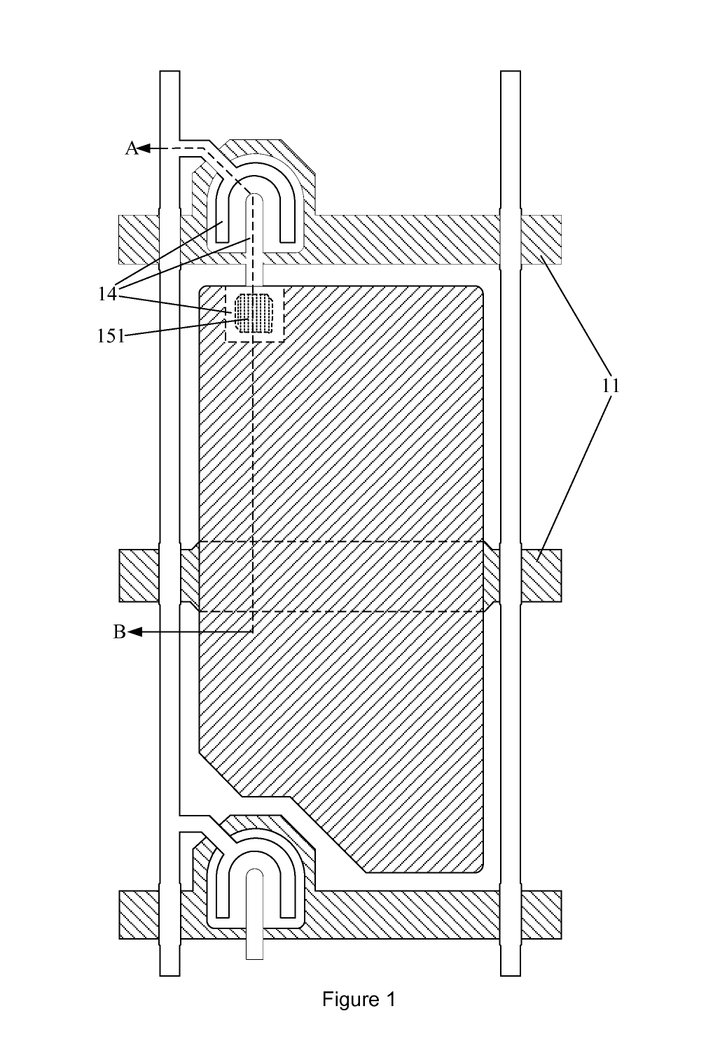

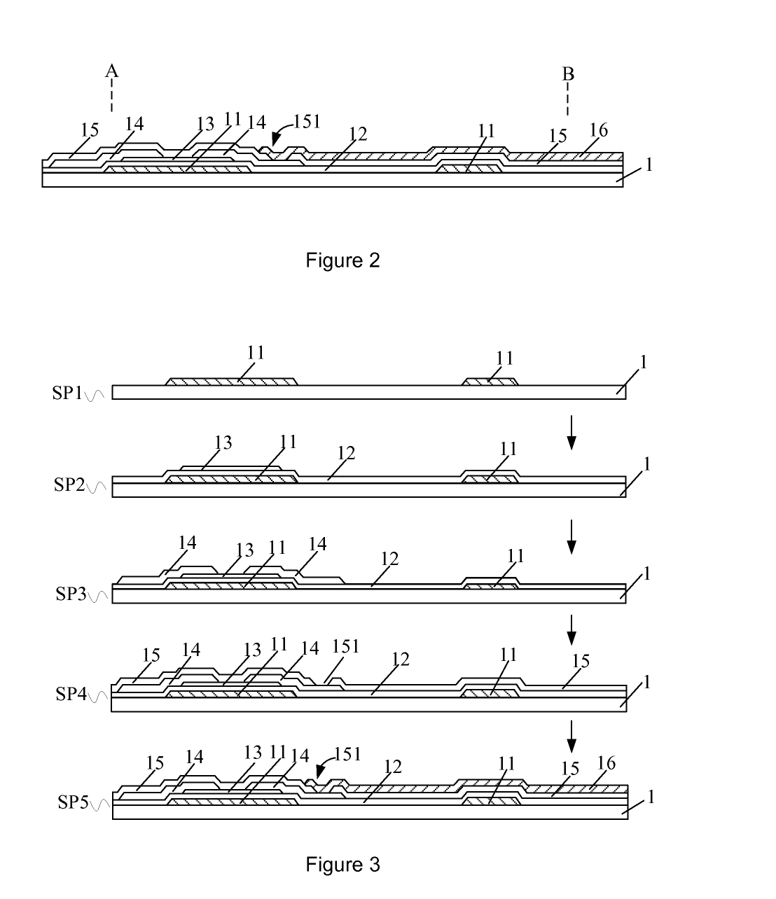

### DETAILED DESCRIPTION OF THE PREFERRED EMBODIMENTS

The liquid crystal display device, array substrate and the manufacturing of the present invention can reduce the possibility of electrostatic explosion during array substrate manufacturing process and improve the yield rate of array substrate.

The following refers to the drawings and the embodiments to describe the present invention in details.

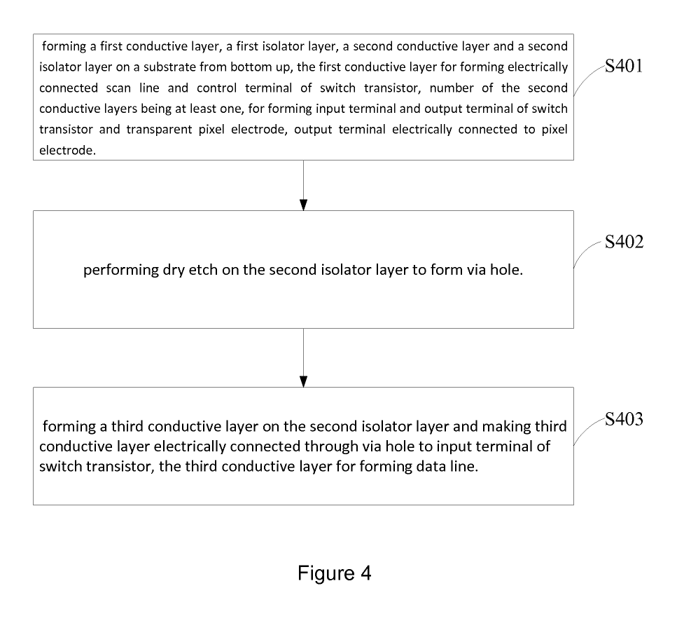

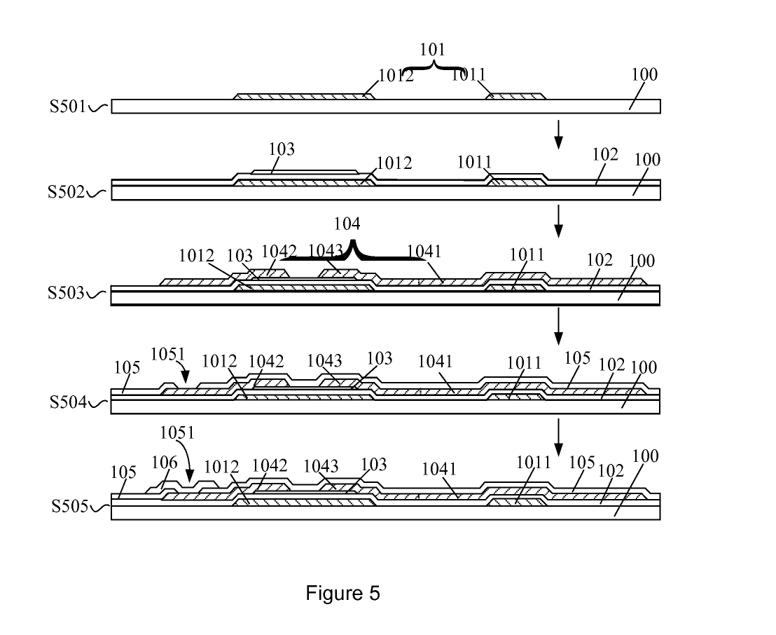

Referring to FIGS. 4 and 5, an embodiment of the array substrate manufacturing method of the present invention comprises the following:

Step S401: forming a first conductive layer, a first isolator layer, a second conductive layer and a second isolator layer on a substrate from bottom up, the first conductive layer for forming electrically connected scan line and control terminal of switch transistor, number of the second conductive layers being at least one, for forming input terminal and output terminal of switch transistor and transparent pixel electrode, output terminal electrically connected to pixel electrode.

The scan line, data line, pixel electrode and switch transistor are main circuit components of array substrate, and a clean smooth surface glass is the substrate to start the array substrate. With glass as substrate, the main circuit components, such as, scan line, data line, pixel electrode and switch transistor are formed on the substrate through performing coating and etch techniques. In the instant embodiment, switch transistor is a thin film transistor, the control terminal, input terminal and output terminal of the switch transistor are the gate terminal, source terminal and drain terminal of the thin film transistor respectively.

Specifically, the manufacturing process, as shown in FIG. 5, comprises the following sub-steps:

Sub-step S501: forming the first metal layer 101 on the substrate 100, the first metal layer for forming electrically connected (not shown) scan line 1011 and gate terminal 1012, in the subsequent process, scan signal being supplied through scan line 1011 to gate terminal 1012 of thin film transistor.

Sub-step S502: forming the first isolator layer 102 on scan line 1011 and gate terminal 1012 of the thin film transistor after forming scan line 1011 and gate terminal 1012 of the thin film transistor.

Furthermore, a semiconductor layer 103 is formed on top of the first isolator layer corresponding to the gate terminal 1012 of thin film transistor after the first isolator layer 102 is formed in top of scan line 1011 and gate terminal 1012 of the thin film transistor.

Sub-step S503: forming the second conductive layer 104 on top of the first isolator layer 102, scan line 1011 and gate terminal 1012 of the thin film transistor being electrically isolated from the second conductive layer 104 by the first isolator layer 102. The second conductive layer is for forming transparent pixel electrode 1041 and source terminal 1042 and drain terminal 1043 of thin film transistor. Also, in the forming process, source terminal 1042 and drain terminal 1043 of thin film transistor are connected respectively to semiconductor layer 103. The thin film transistor realizes the function of the switch through the semiconductor layer 103. Specifically, gate terminal 1012 of thin film transistor is used as the control terminal. When scan line 1011 supplies scan signal to gate terminal 1012 of thin film transistor, the semiconductor layer 103 is conductive so that the thin film transistor is in conductive state, and the source terminal 1042 serving as input terminal of the thin film transistor and the drain terminal 1043 serving as output terminal of the thin film transistor are electrically connected through semiconductor layer 103. When scan line 1011 does not supply scan signal to gate terminal 1012 of thin film transistor, the semiconductor layer 103 is non-conductive so that the thin film transistor is in non-conductive state, and the source terminal 1042 and the drain terminal 1043 are electrically isolated from each other.

In addition, when second conductive layer 104 forms transparent pixel electrode 1041, pixel electrode 1041 is electrically connected to drain terminal 1043 of thin film transistor so that display signal can be inputted through drain terminal 1043 to pixel electrode 1041 in subsequent process.

Sub-step S504: the second isolator layer 105 is formed on top of the second conductive layer 104 after the second conductive layer 104 is formed. In the instant embodiment, the second isolator layer can be passive layer, or other isolator layer with isolating characteristics. No specific restriction is stated here.

Step S402: performing dry etch on the second isolator layer to form via hole.

After forming second isolator layer 105 on top of second conductive layer 104, second isolator layer 105 covers source terminal 1042 of thin film transistor with an isolator layer (i.e., isolator layer 105). As source terminal 1042 is the input terminal of thin film transistor, the input signal from source terminal 1042 is definite required. Therefore, dry etch is performed on second isolator layer 105 corresponding to source terminal 1042 of thin film transistor so as to form via hole 1051 on second isolator layer 105 corresponding to source terminal 1042 of thin film transistor to enable supplying input display signal to source terminal 1042.

In the instant embodiment, performing dry etch is to use plasma etching to perform dry etch. Specifically, the plasma based dry etch is through active plasma to perform physical bombardment and chemical reaction on the second isolator layer 105 to form via hole 1051 on second isolator layer 105 corresponding to source terminal 1042 of thin film transistor to enable. In other embodiments, dry etch based on physical etch or chemical etch can also be used on the second isolator layer 105 to form via hole 1051. No specific restriction is stated here.

Step S403: forming a third conductive layer on the second isolator layer and making third conductive layer electrically connected through via hole to input terminal of switch transistor, the third conductive layer for forming data line.

Sub-step S505: forming a third conductive layer 106 at the location of via hole 1051 on the second isolator layer 105 and making third conductive layer 106 electrically connected through via hole 1051 to source terminal 1042 of thin film transistor serving as switch transistor. The third conductive layer 106 is for forming data line.

After the above step, scan line 1011, data line (formed by third conductive layer 106) and pixel electrode 1041 are formed on substrate 100. The formed semiconductor layer 103, gate terminal 1012, source terminal 1042 and drain terminal 1043 form the thin film transistor required by substrate 100. At the time when scan line 1011 inputting scan signal to gate terminal 1012 of thin film transistor, the semiconductor layer 103 is conductive so that thin film transistor is conductive, the data line supplies display signal through via hole 1052 to source terminal 1042 of thin film transistor, and the display signal is outputted from drain terminal 1043 to pixel electrode 1041.

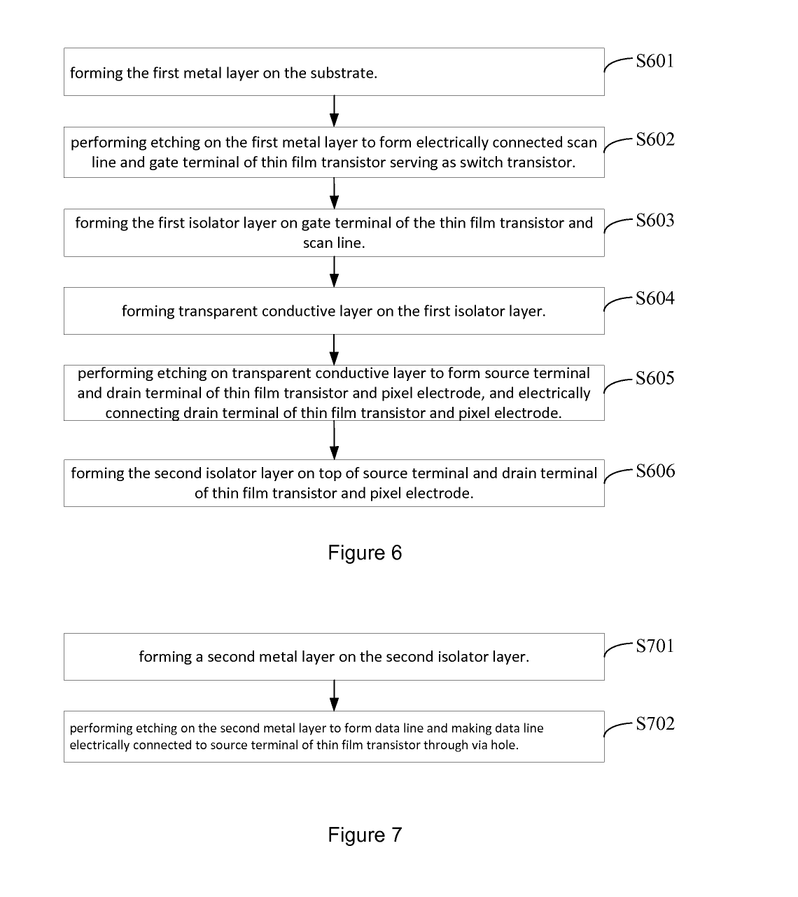

It should be noted that, referring to FIG. 6 in combination with FIG. 5, in a specific embodiment, first conductive layer 101 and third conductive layer 106 are first metal layer and second metal layer respectively. Second conductive layer 104 is transparent conductive layer. Therefore, the step of forming a first conductive layer 101, a first isolator layer 102, a second conductive layer 104 and a second isolator layer 105 on a substrate 100 from bottom up specifically comprises:

Step S601: forming the first metal layer on the substrate.

Step S602: performing etching on the first metal layer to form electrically connected scan line and gate terminal of thin film transistor serving as switch transistor.

Step S603: forming the first isolator layer on gate terminal of the thin film transistor and scan line.

Step S604: forming transparent conductive layer on the first isolator layer.

Step S605: performing etching on transparent conductive layer to form source terminal and drain terminal of thin film transistor and pixel electrode, and electrically connecting drain terminal of thin film transistor and pixel electrode.

Step S606: forming the second isolator layer on top of source terminal and drain terminal of thin film transistor and pixel electrode.

In other embodiments of the present invention, source terminal 1042 and drain terminal 1043 of thin film transistor can be formed by metal conductive layer. Therefore, the number of second conductive layers 104 can be two, comprising transparent conductive layer for forming pixel electrode 1041 and third metal layer (not shown) for forming source terminal 1042 and drain terminal 1043 of thin film transistor. Third metal layer for forming drain terminal 1043 of thin film transistor and transparent conductive layer for forming pixel electrode 1041 are made electrically connected so as to realize electrical connection between drain terminal 1043 of thin film transistor and pixel electrode 1041.

After forming the second isolator layer, dry etch is performed on the second isolator layer to form via hole.

Refer to FIG. 7. The specific steps of forming the third conductive layer on the second isolator layer to make the third conductive layer electrically connected to input terminal of switch transistor through via hole comprise:

Step S701: forming a second metal layer on the second isolator layer.

Step S702: performing etching on the second metal layer to form data line and making data line electrically connected to source terminal of thin film transistor through via hole.

For those skilled in the related technical field can easily understand how FIGS. 6 and 7 are realized after referring to the description of FIGS. 4 and 5. Thus, the description will be omitted here.

In summary, the manufacturing method for array substrate of the present invention forms the first conductive layer 101 for scan line 1011 and gate terminal 1012 of thin film transistor, then forms first isolator layer 102, second conductive layer 104 and second isolator layer 105 subsequently, performs dry etch to form via holes 1051 on the second isolator layer 105, and finally forms the third conductive layer 106 on top of the second isolator layer 105 for data line. Because when performing dry etch on the second conductive layer 105 to form via holes 1061, the third conductive layer 106 for data line is yet formed, no scan line 1011 and data line overlapping area exists when performing dry etch. Therefore, the present invention can reduce the possibility of electrostatic explosion during array substrate manufacturing process and improve the yield rate of array substrate.

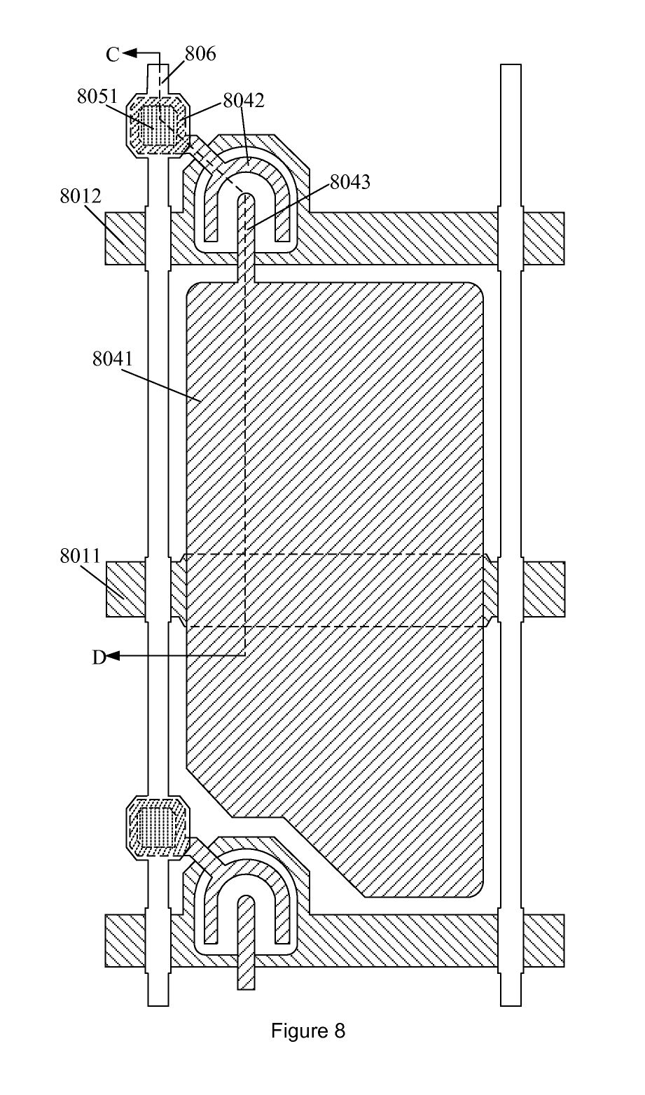

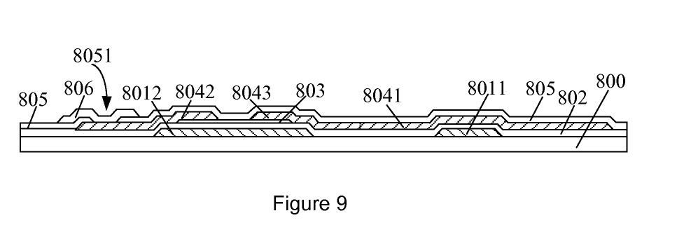

Referring to FIGS. 8 and 9, an embodiment of an array substrate of the present invention comprises: a substrate 800; scan line 8011 and control terminal 8012 of switch transistor, disposed on the substrate 800 and electrically connected to each other; a first isolator layer 802, disposed on top of scan line 8011 and control terminal 8012 of switch transistor; input terminal 8042 and output terminal 8043 of switch transistor and transparent pixel electrode 8041, disposed on top of the first isolator layer 802, output terminal 8043 electrically connected to pixel electrode 8041, semiconductor 803 being disposed between output terminal 8043 and input terminal 8042; a second isolator layer 805, disposed on top of input terminal 8042 and output terminal 8043 of switch transistor and pixel electrode 8041, via hole 8051 being disposed on the second isolator layer 805 at locations corresponding to input terminal 8042 of switch transistor; and data line 806, disposed on via hole 8051 area of the second isolator layer 805, data line 806 electrically connected through via hole 8051 to input terminal 8042 of switch transistor.

It should be noted that, to clearly illustrate the layout and structure of main components of the array substrate circuit of the present invention, the schematic view of the array substrate in FIG. 8 is simplified. For example, first isolator layer 802 and second isolator layer 805 are not shown in FIG. 8. Also, input terminal 8042 of switch transistor and via hole 8051 covered by data line 806 are shown.

In the instant embodiment, the switch transistor is a thin film transistor. Control terminal 8012 is the gate terminal of the thin film transistor. Input terminal 8042 and output terminal 8043 are the source terminal and drain terminal of the thin film transistor, respectively. Also, the source terminal and drain terminal of the thin film transistor and pixel electrode 8041 all belong to the same transparent conductive layer.

The array substrate of the instant embodiment, through last forming data line 806 on the area of via hole 8051 on second isolator layer 805 so that data line 806 is not formed yet when forming via hole 8051 on second isolator layer 805, avoids the overlapping area of scan line 8011 and data line 806 overlapping area exists when forming via hole 8051. As such, the present invention can reduce the possibility of electrostatic explosion during array substrate manufacturing process and improve the yield rate of array substrate.

The present invention further provides a liquid crystal display device, comprising any array substrate formed by aforementioned methods.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

What is claimed is:

1. A manufacturing method for array substrate, which comprises:
forming a first conductive layer, a first isolator layer, a second conductive layer and a second isolator layer on a substrate from bottom up, the first conductive layer for forming electrically connected scan line and control terminal of switch transistor, number of the second conductive layers being at least one, for forming input terminal and output terminal of switch transistor and transparent pixel electrode, output terminal electrically connected to pixel electrode;
performing dry etch on the second isolator layer to form via hole;
forming a third conductive layer on the second isolator layer and making third conductive layer electrically connected through via hole to input terminal of switch transistor, the third conductive layer for forming data line;
wherein the step of forming a first conductive layer, a first isolator layer, a second conductive layer and a second isolator layer on a substrate from bottom up comprising:
forming the first metal layer on the substrate;
performing etching on the first metal layer to form electrically connected scan line and gate terminal of thin film transistor serving as switch transistor;
forming the first isolator layer on gate terminal of the thin film transistor and scan line;
forming transparent conductive layer on the first isolator layer;
performing etching on transparent conductive layer to form source terminal and drain terminal of thin film transistor and pixel electrode, and electrically connecting drain terminal of thin film transistor and pixel electrode;
forming the second isolator layer on top of source terminal and drain terminal of thin film transistor and pixel electrode; and
the step of performing dry etch on the second isolator layer to form via hole comprising:
performing dry etch on the second isolator layer corresponding to source terminal of thin film transistor to form via hole between the second isolator layer and source terminal of thin film transistor.

2. The manufacturing method as claimed in claim 1, characterized in that:
a step after forming the first isolator layer on gate terminal of the thin film transistor and scan line comprises:
forming a semiconductor layer on the first isolator layer corresponding to gate terminal of thin film transistor and making source terminal and drain terminal of thin film transistor connected respectively to the semiconductor layer.

3. The manufacturing method as claimed in claim 1, characterized in that:
the step of performing dry etch on the second isolator layer corresponding to source terminal of thin film transistor comprises:
using dry etch based on plasma etching to perform dry etch on the second isolator layer corresponding to source terminal of thin film transistor.

4. The manufacturing method as claimed in claim 3, characterized in that:
the step of forming a third conductive layer on the second isolator layer and making third conductive layer electrically connected through via hole to input terminal of switch transistor comprises:
forming the second metal layer on the second isolator layer;
performing etching on the second metal layer to form data line and making data line electrically connected through via hole to source terminal of thin film transistor.

5. An array substrate, which comprises:
a substrate;
scan line and control terminal of switch transistor, disposed on the substrate and electrically connected to each other;
a first isolator layer, disposed on top of scan line and control terminal of switch transistor;
input terminal and output terminal of switch transistor and transparent pixel electrode, disposed on top of the first isolator layer, output terminal electrically connected to pixel electrode, semiconductor being disposed between output terminal and input terminal;
a second isolator layer, disposed on top of input terminal and output terminal of switch transistor and pixel electrode, via hole being disposed on the second isolator layer at locations corresponding to input terminal of switch transistor; and
data line, disposed on via hole area of the second isolator layer, data line electrically connected through via hole to input terminal of switch transistor.

6. The array substrate as claimed in claim 5, characterized in that:
the switch transistor is thin film transistor, the control terminal is gate terminal of the thin film transistor, the input terminal and the output terminal are source terminal and drain terminal of the thin film transistor respectively.

7. The array substrate as claimed in claim 6, characterized in that:
the source terminal and the drain terminal of the thin film transistor and the pixel electrode belong to a transparent conductive layer.

8. A liquid crystal display device, which comprises: an array substrate, the array substrate comprises:
a substrate;
scan line and control terminal of switch transistor, disposed on the substrate and electrically connected to each other;
a first isolator layer, disposed on top of scan line and control terminal of switch transistor;
input terminal and output terminal of switch transistor and transparent pixel electrode, disposed on top of the first isolator layer, input terminal electrically connected to pixel electrode, semiconductor being disposed between output terminal and input terminal;
a second isolator layer, disposed on top of input terminal and output terminal of switch transistor and pixel electrode, via hole being disposed on the second isolator layer at locations corresponding to input terminal of switch transistor; and
data line, disposed on via hole area of the second isolator layer, data line electrically connected through via hole to input terminal of switch transistor.

9. The liquid crystal display device as claimed in claim 8, characterized in that:
the switch transistor is thin film transistor, the control terminal is gate terminal of the thin film transistor, the input terminal and the output terminal are source terminal and drain terminal of the thin film transistor respectively.

10. The liquid crystal display device as claimed in claim 9, characterized in that:
the source terminal and the drain terminal of the thin film transistor and the pixel electrode belong to a transparent conductive layer.
